(19) United States
(12) Patent Application Publication
(10) Pub. No.: US 2009/0146299 A1
(43) Pub. Date: Jun. 11, 2009

(54) SEMICONDUCTOR PACKAGE AND METHOD THEREOF

(76) Inventor: Shih-Chi CHEN, Hsinchu City (TW)

Correspondence Address: SINORICA, LLC, 528 FALLSGROVE DRIVE, ROCKVILLE, MD, 20850, US

(21) Appl. No.: 12/113,906

(22) Filed: May 1, 2008

(30) Foreign Application Priority Data
Dec. 10, 2007 (TW) 096146964

(51) Int. Cl. H01L 23/488; H01L 21/56

(52) U.S. Cl. 257/738; 438/114; 257/E23.023; 257/E21.502

(57) ABSTRACT

A ball grid array (BGA) structure package includes: a circuit board including a top surface and a bottom surface, and the top surface includes a patterned metal point disposed thereon and the bottom surface includes a metal point corresponding to the patterned conductive point; a semiconductor die includes an active surface, and the active surface includes a plurality of pads disposed thereon and the pads is electrically connected to the patterned metal point; a package body used to encapsulate the semiconductor die and the top surface of the circuit board; and a plurality of conductive elements electrically connected to the bottom surface of the circuit board.

### BACKGROUND OF THE INVENTION

1. Field of the Invention

The present invention is a semiconductor package structure and method thereof, and more particularly, is a ball grid array (BGA) package structure and method thereof to electrically connect the dies and a conductive point of a carrier substrate.

2. Description of the Prior Art

In these few years, because the semiconductor manufacture technique is well developed, the high quality of the electronic device is become smaller with more functions. There are many small integrated circuit (IC) disposed inside the electronic device. That is the reason why the electronic device is able to have so many different functions. During the electronic device manufacture period, the IC package is an important issue. The IC package method includes dual in line package (DIP), ball grid array package (BGA), tape automatic bonding (TAB) and so on. Such as BGA, the package technique is using solder balls disposed in the whole carrier substrate to replace the conventional lead-frame pins.

The BGA uses wire bonding or flip die to electrically connect the conductive points of the die and the carrier substrate. The internal wire layer of the carrier substrate is connected to the bottom of the carrier board. The ball mount process is used to implant the solder balls on the conductive points disposed at the carrier substrate. The conductive points described above include solder ball pads structure. Because the BGA package is able to use the whole area of the carrier substrate to be the conductive points, the number of pins is more than the conventional package technique. However, because the semiconductor is highly developed, the dies with more pins is developed. Because there are more and more pins in the dies, the conductive points are closed to each other and the signal cross-talk problem is occurred. Except the signal cross-talk problem described above, there is more pressure generated during implanting the solder balls. Therefore, the dies' damage will occur. Therefore, how to design a wire layout in chips with high pins is a problem needed to be solved.

In the conventional technique, after the wafer was cut into several chips, the chips were disposed on another carrier substrate by a manufacture equipment to let chips have more room. Therefore, the fan out technique is used in the package process to distribute over the conductive points on the chips. Those conventional techniques were disclosed in some US patent application, such as U.S. Pat. No. 6,727,576, U.S. Pat. No. 7,074,696, and U.S. Pat. No. 7,061,123 and so on. Besides, in different technique, there is a conductive buffer, such as polymer bump, disposed between the connecting point and the solder ball and used to absorb the pressure for the chips generated during implanting the solder balls, such as U.S. Pat. Nos. 7,157,353 and 7,022,1059. However, the prior arts described above are complicated manufacture procedures. In U.S. Pat. No. 7,074,696, it is disclosed a technique that a patterned dielectric layer is formed on the carrier substrate and the chips are connected to the dielectric layer. The conductive points are disposed between the patterned dielectric layers. After the carrier substrate is removed, the metal leads are directly disposed on the dielectric layer. Therefore, there is a need to provide a convenience package structure and method to simplify the package process and shorten the manufacture time.

### SUMMARY OF THE INVENTION

According to the problems described above, the main object of the present invention is to provide a ball grid array package method to enhance the reliability of the package structure.

The other object of the present invention is to provide a BGA package structure that an encapsulated material and a circuit board are used to cover the dies to enhance the efficiency of the package.

According to the objects above, A ball grid array (BGA) structure package method includes the following steps: providing a substrate, which includes a first surface and a second surface; forming a polymer material layer on the first surface of the substrate, the polymer material includes a top surface and a bottom surface and the bottom surface is formed on the first surface of the substrate; forming a plurality of metal points on the top surface of the polymer material layer, each of the metal points includes an extended portion, a front surface and a back surface, the back surface of the metal points is formed on the top surface of the polymer material layer; providing a plurality of semiconductor dies, each of the semiconductor dies includes an active surface, and a plurality of pads is disposed on the active surface; adhering to the semiconductor dies, and the pads on the active surface of the semiconductor die is electrically connected with one end of the front surface of the extended portion of the metal point; executing a molding material to encapsulate the semiconductor dies and the top surface of the polymer material layer; removing the polymer material layer and the substrate to expose the top surface of the extended portion of each of the metal points; and forming a plurality of conductive elements, and the conductive elements are electrically connected to the front surface on the other end of the extended portion of the metal points.

A ball grid array (BGA) structure package method includes the following steps: providing a circuit board, which includes a top surface and a bottom surface, the top surface includes a plurality of patterned conductive points disposed thereon and the bottom surface includes a plurality of metal points corresponding to the patterned conductive points; adhering to the bottom surface of the circuit board on a first surface of a carrier substrate; providing a plurality of semiconductor dies and each of the semiconductor dies includes an active surface including a plurality of pads disposed thereon; adhering to the semiconductor dies, and the pads of the active surface on the semiconductor die is electrically connected to the conductive points; executing a molding material to encapsulate the semiconductor dies and the top surface of the circuit board; removing the carrier substrate to expose the top surface of the extended portion of each of the metal points; forming a plurality of conductive elements on the surface of the metal points; and sawing the package body and the circuit board to form a plurality of packaged semiconductor structure.

A ball grid array (BGA) structure package includes: a circuit board including a top surface and a bottom surface, and the top surface includes a patterned metal point disposed thereon and the bottom surface includes a metal point corresponding to the patterned conductive point; a semiconductor die includes an active surface, and the active surface includes a plurality of pads disposed thereon and the pads is electrically connected to the patterned metal point; a package body used to encapsulate the semiconductor die and the top surface of the circuit board; and a plurality of conductive elements electrically connected to the bottom surface of the circuit board.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A and FIG. 1B are top views showing that a carrier substrate includes a polymer material layer and a plurality of patterned conductive points according to the present invention.

FIG. 1C is a sectional view according to FIG. 1A and the AA line segment and BB line segment of FIG. 1B.

FIGS. 2A-2E are views showing that the ball grid array (BGA) package method in the present invention.

FIGS. 3A-3F are views showing the package steps according to another embodiment of the semiconductor die package structure.

FIGS. 4A-4C are views showing that the ball grid array (BGA) package method in another embodiment of the present invention.

### DESCRIPTION OF THE PREFERRED EMBODIMENT

The following detailed description of the present invention describes a semiconductor package structure and method thereof necessary to provide an understanding of the present invention, but does not cover a complete structure composition and the operating theory. The portions relating to the conventional techniques are briefly described, and the parts of the drawings are not proportionally drafted. While embodiments are discussed, it is not intended to limit the scope of the present invention. Except expressly restricting the amount of the components, it is appreciated that the quantity of the disclosed components may be greater than that disclosed.

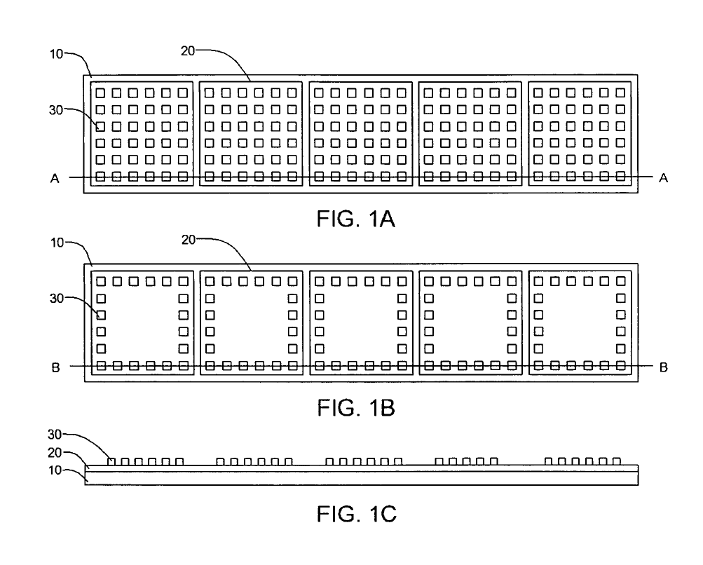

Please refer to FIG. 1A and FIG. 1B; those are top views of the carrier substrate disposing a polymer material layer and some patterned conductive points in the present invention. As shown in FIG. 1A and FIG. 1B, a carrier substrate 10 is provided and the carrier substrate 10 is a transparent material, such as glass or optical glass, or non-transparent material. And a polymer material layer 20 is formed on the carrier substrate 10 by coating or printing. In a preferred embodiment, the polymer material layer 20 is a photoresist layer. After forming the polymer material layer 20, there are a plurality of patterned conductive points 30 disposed on the middle area of the polymer material layer 20 in array layout, as shown in FIG. 1A. Besides, in a different embodiment, the patterned conductive points 30 are formed in the area all around the polymer material layer 20. In the embodiment of the present invention, the method to form the patterned conductive points on the polymer material layer 20 which includes: forming a conductive layer (not shown) on the polymer material layer 20; forming a patterned photoresist layer (not shown) on the conductive layer; processing a eroding step to remove a portion of conductive layer and forming a plurality of patterned conductive points 30. In the preferred embodiment of the present invention, the conductive points are flexible conductive material, such as conductive polymer bump. Now please refer to FIG. 1C, it is a sectional view according to FIG. 1A and the AA and BB line segments in FIG. 1B. It should be noted that the AA and BB line segments chosen in the sectional view are used for the detail description in the embodiment. In other words, the pads are disposed around the area of the active surface of the chip and the pads are disposed on the active surface of the chip by array layout that is showing in FIG. 1C.

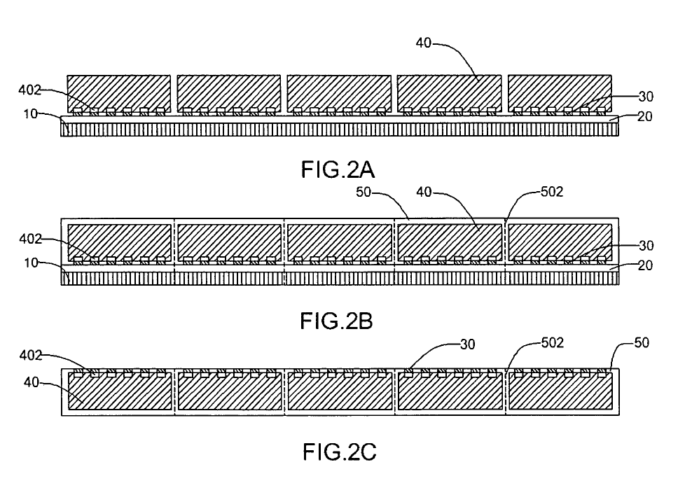

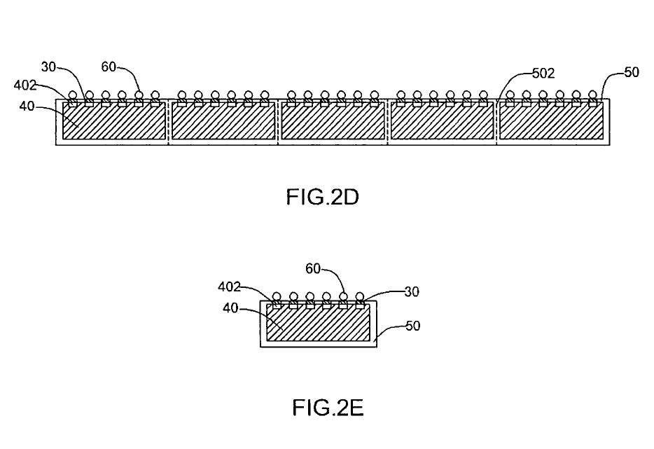

Now please refer to FIG. 2A to FIG. 2E, those are views showing the ball grid array package method in the present invention. The good dies 40, which had been tested and sawed, are picked and place by a machine arm. The pads on the active surface of the die 40 are electrically adhered to the front surface of the patterned conductive points on the polymer material layer 20 of the carrier substrate 10. In this embodiment, there is a conductive glue (not shown), such as paste, formed between the pads 402 and the conductive points 30.

In FIG. 2B, after the dies 40 is adhered on the conductive points 30, a molding step is to form an encapsulant material 50 used to cover the dies 40 and the top surface of the polymer material layer 20. The encapsulant material is epoxy or colloid.

After the molding step, a remove step is used to remove the carrier substrate 10 and the polymer material layer 20 and expose each of the conductive points 30. After removing the carrier substrate 10 and the polymer material layer 20, the package body is upside down for the following implant procedure. As shown in FIG. 2C, the conductive points 30 are flexible polymer bumps. Please continue referring to FIG. 2D, it is a view showing that a plurality of conductive elements 60 are formed on the front surface of each of the conductive points 30 and electrically connected. The conductive elements 60 are solder balls or metal bumps. After the electrical connection of the conductive elements 60 and the conductive points 30 as shown in FIG. 2E, the sawing process is used to saw the dies 40 in accordance with the sawing line 502 between the dies 40 and a plurality of BGA packaged structures. Obviously, after the steps shown in FIG. 2A to FIG. 2E, the BGA package includes a plurality of patterned conductive points 30, a semiconductor die 40, an encapsulant material 50 and a plurality of conductive elements 60. The conductive points 30 include a front surface and a reverse surface. The active surface of the semiconductor dies 40 includes a plurality of pads 402. The pads 402 are electrically connected to the front surface of the conductive points 30. The encapsulant material 50 is used to cover the semiconductor dies 40. The conductive elements 60 are electrically connected to the front surface of each of the conductive points 30. It should be noted that a polymer material layer 20 is able to be formed on the carrier substrate 10 in the present embodiment. Then, the patterned conductive points 30 are formed on the polymer material layer 20. After forming the patterned conductive points 30 on the polymer material layer 20, the good dies 40 are adhered to the patterned conductive points 30. After the carrier substrate 10 and the polymer material layer 20 are removed, the conductive points 30 are stayed on the pads of the semiconductor chip 40 in order to execute a sawing step. Therefore, the package steps can be simplified. It is clear to see that the package process and the structure in the present embodiment are different to U.S. Pat. No. 7,074,696.

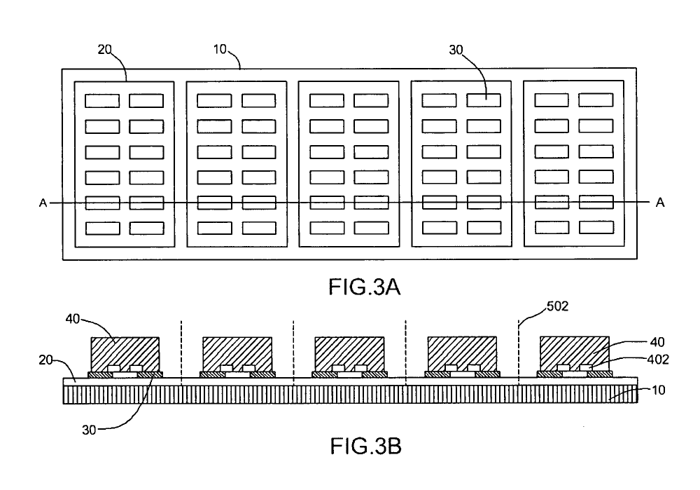

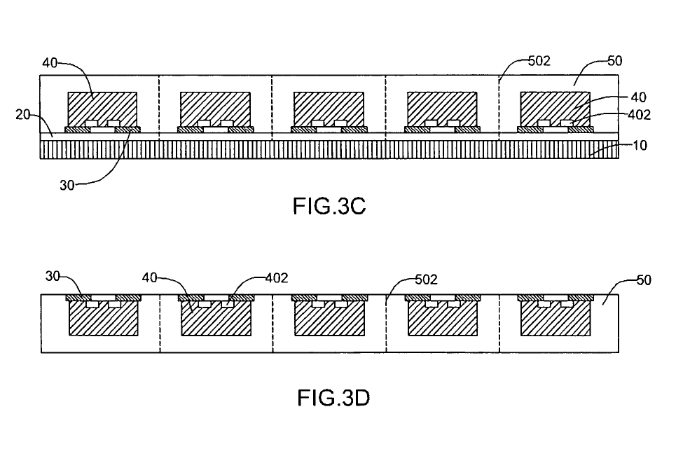

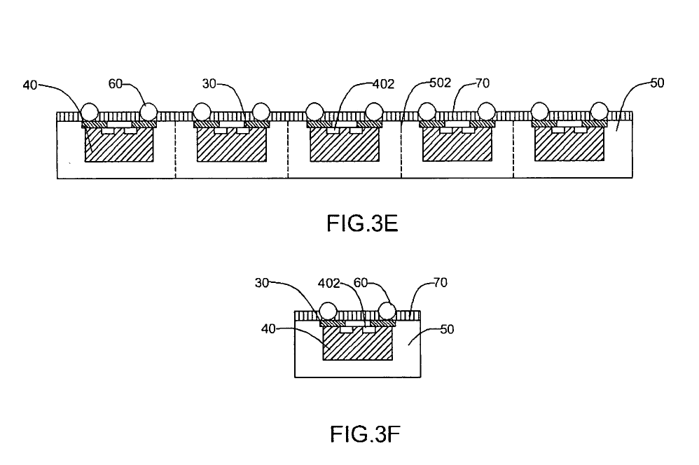

Please refer to FIG. 3A and FIG. 3F; those are views showing another semiconductor die package method. As shown in FIG. 3A, it is a top view showing that the polymer material layer 20 on the first surface of the carrier substrate 10 includes a plurality of patterned metal layer 30. The method of forming the metal layer 30 is similar to the previous embodiment described above. The metal layers 30 are longitudinally extended longer in the present invention. As shown in FIG. 3B, it is a top view showing that the conductive elements are formed on the metal layer. FIG. 3F is showing that the BGA package structure is formed. At first, as shown in FIG. 3A, there is a carrier substrate 10 provided. The carrier substrate 10 is a transparent material, such as glass or optical glass, or non-transparent material. And a polymer material layer 20 is formed on the carrier substrate 10. The polymer material layer 20 is a photoresist layer. After forming the polymer material layer 20, there are a plurality of patterned conductive points 30 disposed on the top surface of the polymer material layer 20. The patterned metal layer 30 are longitudinally extended longer and alternatively and respectively paralleled to each other.

The pads 402 on the active surface of the die 40 are adhered to the corresponding metal layers 30 by the flip chip method. The pads 402 are electrically connected to one end of the metal layers 30. The other end of the metal layer 30 is extended over the size of the dies 40, as shown in FIG. 3B. After the dies 40 is adhered on the metal layers 30, a molding step is to form an encapsulant material 50 used to cover the dies 40 and the top surface of the polymer material layer 20, as shown in FIG. 3C. The encapsulant material 50 is epoxy or colloid. After the molding step, a removing step is used to remove the carrier substrate 10 and the polymer material layer 20 and expose the surface of the metal layers 30. Then, there is a protective layer 70 formed on the surface of the metal layer 30 to expose a portion of each of the metal layers 30, as shown in FIG. 3D. A plurality of conductive elements 60 is formed on the exposed and patterned metal layer 30. The conductive elements are formed on one end of the extended metal layer 302 (the other end of the pads 402). Obviously, it is fan out structure and the conductive elements are solder balls or metal bumps, as shown in FIG. 3E. After electrically connecting the conductive elements and the metal layers 30, a sawing process is used to saw the dies 40 in accordance with the sawing line 502 between the adjacent semiconductor dies 40 to form the package structure, as shown in FIG. 3F.

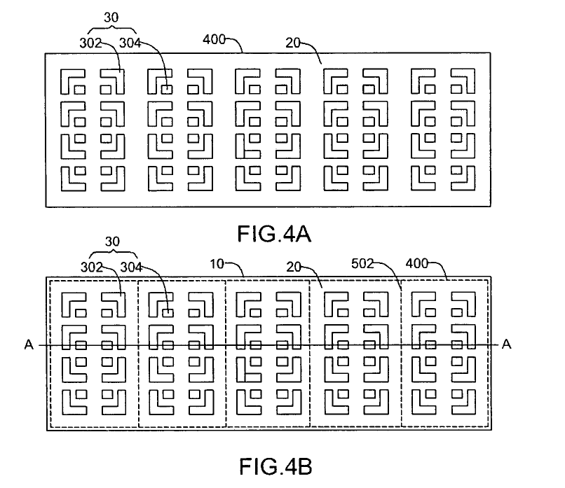

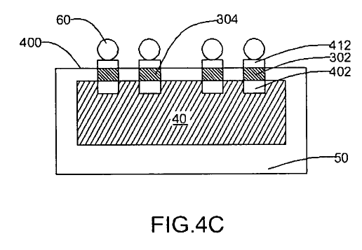

Please refer to FIG. 4A and FIG. 4C, those are views showing another BGA package method. First of all, there is a patterned conductive points 30 formed on a top surface of a circuit board 400. In this embodiment, the circuit board 400 can be a flexible or a rigid and formed by a single layer or multi layers. The bottom surface of the circuit board 400 includes a plurality of metal points 412 (not shown in FIG. 4A). The metal points 412 are used to electrically connect to the conductive points 30. Obviously, the metal points are passing through the top surface and the bottom surface of the circuit board 400. And the patterned conductive points 30, the shorter metal layer 304 and the longer metal layer 302 are respectively and alternatively paralleled to each other. One end of each of the longer metal layer 302 is formed with geographic shape and is in the same horizontal line as the end of the shorter metal layer 304. The geographic shape is an L shape or curved shape, as shown in FIG. 4A. It should be noted that the conductive points 30 is formed by the shorter metal layer 304 and the longer metal layer 302 is just an embodiment of the present invention, it is not used to limit the method in the present invention. Therefore, the conductive point 30 is able to connect to the pads on the dies by request, such as shown in FIG. 1A, FIG. 1B, or FIG. 3A.

The bottom surface of the metal points 412 of the circuit board 400 is adhered to a carrier substrate 10, as shown in FIG. 4B. The molding step is used to form an encapsulant material 50 used to cover the dies 40 and the top surface of the circuit board 400. The encapsulant material is an epoxy or a colloid. After the molding step, a removing step is used to remove the carrier substrate 10 and expose the metal points 412 (as shown in FIG. 4C) of the surface of the circuit board 400. Then, a plurality of conductive elements 60 are formed on the metal points 412 (as shown in FIG. 4C). The conductive elements are solder balls or metal bumps. Eventually, a sawing process is used to saw the dies 40 in accordance with the sawing line 502 between the adjacent semiconductor dies 40 to form the package structure, as shown in FIG. 4C.

Obviously, the package steps described above is to cover the dies 400 by the encapsulated material 50 and the circuit board 400 and then the sawing step is proceeded. Therefore, the die 40 is not going to be polluted during the sawing step and enhance the efficiency of the package process.

According to the process described above, the BGA package structure shown in FIG. 4C includes a circuit board 400. The circuit board 400 includes a top surface and the bottom surface. The top surface of the circuit board 400 includes a plurality of patterned conductive points 30. The bottom surface of the circuit board 400 includes a plurality of metal points 412 electrically connected to the patterned conductive points 30. The active surface of the die 40 includes a plurality of pads electrically connected to the patterned conductive points 30. An encapsulant material 50 is used to cover the semiconductor dies 40 and the top surface of the circuit board 400. Then, the conductive elements 60 are electrically connected to the metal points 412 of the bottom of the circuit board 400.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly and legally entitled.

What is claimed is:

1. A ball grid array structure package method comprising:
providing a substrate, which includes a first surface and a second surface;
forming a polymer material layer on the first surface of the substrate, the polymer material includes a top surface and a bottom surface and the bottom surface is formed on the first surface of the substrate;
forming a plurality of metal points on the top surface of the polymer material layer, each of the metal points includes an extended portion, a front surface and a back surface, the back surface of the metal points is formed on the top surface of the polymer material layer;
providing a plurality of semiconductor dies, each of the semiconductor dies includes an active surface, and a plurality of pads are disposed on the active surface;
adhering to the semiconductor dies, and the pads on the active surface of the semiconductor die is electrically connected with one end of the front surface of the extended portion of the metal point;
executing a molding material to encapsulate the semiconductor dies and the top surface of the polymer material layer;
removing the polymer material layer and the substrate to expose the top surface of the extended portion of each of the metal points to form a package body; and
forming a plurality of conductive elements, and the conductive elements are electrically connected to the front surface on the other end of the extended portion of the metal points.

2. The package method according to claim 1, wherein the metal points is formed on the polymer material layer by an array method.

3. The package method according to claim 1, wherein the method of forming the metal points comprising:
forming a metal layer on the polymer material layer;
forming a patterned photoresist layer on the metal layer; and
removing a portion of the metal layer to form a plurality of metal points with the same pattern.

4. The package method according to claim 1, wherein the conductive element is solder ball.

5. The package method according to claim 1, wherein the conductive element is metal bump.

6. A ball grid array structure package method comprising:
providing a circuit board, which has a top surface and a bottom surface, the top surface has a plurality of patterned conductive points disposed thereon and the bottom surface has a plurality of metal points corresponding to the patterned conductive points;
adhering to the bottom surface of the circuit board on a first surface of a carrier substrate;
providing a plurality of semiconductor dies and each of the semiconductor dies includes an active surface including a plurality of pads disposed thereon;
adhering to the semiconductor dies, and the pads of the active surface on the semiconductor die is electrically connected to the conductive points;
executing a molding material to encapsulate the semiconductor dies and the top surface of the circuit board;
removing the carrier substrate to expose the top surface of the extended portion of each of the metal points to form a package body;
forming a plurality of conductive elements on the surface of the metal points; and
sawing the package body and the circuit board to form a plurality of packaged semiconductor structure.

7. The package method according to claim 6, wherein the circuit board is a multi-layer structure.

8. The package method according to claim 6, wherein the circuit board is a flexible multi-layer structure.

9. The package method according to claim 6, wherein the circuit board is a flexible circuit board.

10. The package method according to claim 6, wherein the circuit board is a hardness circuit board.

11. The package method according to claim 6, wherein the conductive elements are solder balls.

12. The package method according to claim 6, wherein the conductive elements are metal bumps.

13. A ball grid array structure package comprising:
a circuit board having a top surface and a bottom surface, and the top surface includes a patterned metal point disposed thereon and the bottom surface includes a metal point corresponding to the patterned conductive point;
a semiconductor die includes an active surface, and the active surface includes a plurality of pads disposed thereon and the pads are electrically connected to the patterned metal points;
a package body used to encapsulate the semiconductor die and the top surface of the circuit board; and
a plurality of conductive elements electrically connected to the bottom surface of the circuit board.

14. The package structure according to claim 13, wherein the patterned conductive point on the top surface of the circuit board is a flexible conductive material.

15. The package structure according to claim 13, wherein the flexible conductive material is a conductive polymer bump.

16. The package structure according to claim 13, wherein the patterned metal point on the top surface of the circuit board is an array structure.

17. The package structure according to claim 13, wherein the circuit board is a flexible circuit board.

18. The package structure according to claim 13, wherein the circuit board is a hardness circuit board.

19. The package structure according to claim 13, wherein the conductive elements are solder balls.

20. The package structure of claim 13, wherein the conductive elements are metal bumps.
